(19) United States
(12) Patent Application Publication
(10) Pub. No.: US 2007/0075375 A1
(43) Pub. Date: Apr. 5, 2007

(54) Field effect semiconductor component and method for its production

(76) Inventors: Jeno Tihanyi, Kirchheim (DE); Nada Tihanyi, Kirchheim (DE); Wolfgang Werner, Munchen (DE)

Correspondence Address: BAKER BOTTS, L.L.P., 98 SAN JACINTO BLVD., SUITE 1500, AUSTIN, TX, 78701-4039, US

(21) Appl. No.: 11/463,755

(22) Filed: Aug. 10, 2006

(30) Foreign Application Priority Data
Aug. 12, 2005 (DE) 10 2005 038 441.2

(51) Int. Cl. H01L 29/76

(52) U.S. Cl. 257/370

(57) ABSTRACT

A field effect semiconductor component has a bipolar transistor structure in a semiconductor body consisting of a lightly doped upper area of a first conductivity type as base region and of a lower heavily doped area as emitter region with a complementary conductivity type. Between the base region and the emitter region, a horizontal pn junction forms. The emitter region is in resistive contact with a large-area emitter electrode on the rear of the semiconductor component. On the top of the semiconductor component, a first insulated gate electrode and a second insulated gate electrode are arranged adjacently in the area close to the surface. A vertical pn junction region insulated from the upper area is arranged in such a manner that a collector region and the base region of the bipolar transistor structure can be controlled via the insulated gate electrodes (G₁ and G₂) arranged electrically separately.

### PRIORITY

This application claims priority from German Patent Application No. DE 10 2005 038 441.2, which was filed on Aug. 12, 2005, and is incorporated herein by reference in its entirety.

### TECHNICAL FIELD

The invention relates to a field effect semiconductor component with bipolar transistor structure in a semiconductor body, and to a method for producing the field effect semiconductor component.

### BACKGROUND

Such a field effect semiconductor component with bipolar transistor structure is known from the printed document U.S. Pat. No. 6,627,961 B1 and comprises, in a semiconductor body, a bipolar structure in the form of a discrete IGBT (insulated-gate bipolar transistor) structure and a power MOSFET, the area ratio between the area of the MOSFET semiconductor body and the area of the IGBT semiconductor body being about 25%. In this arrangement, the two structures alternate in the lateral direction and overlap with respect to their p⁺ injection regions and their n⁺ contact areas in the area close to the bottom of the semiconductor body, maintaining a distance of preferably one minority charge carrier diffusion length of between 50 and 100 micrometers for a 1500 V component between the MOSFET and the IGBT structure.

The disadvantage of this high-voltage-MOSFET-connected semiconductor component is its high requirement for area resulting from the relatively large distance between the MOSFET structure and the IGBT structure.

### SUMMARY

According to an embodiment, a semiconductor body may utilize the advantages of combining a MOSFET structure and an IGBT structure but is constructed more compactly and, thus, makes better use of the semiconductor body than is known from the prior art.

According to an embodiment, a field effect semiconductor component with bipolar transistor structure in a semiconductor body is created which can be built-up of a lightly doped upper area of a first type of conduction as base region and a lower heavily doped area as emitter region of a type of conduction complementary to the first type of conduction. In this arrangement, a continuously horizontal pn junction extends between the two areas, the emitter region being in ohmic contact with a large-area electrode on the rear of the field effect semiconductor component. On the top of the field effect semiconductor component, a first insulated gate electrode and a second insulated gate electrode are arranged adjacently to a vertical pn junction close to the surface and insulated from the upper area, in such a manner that a collector region and the base region of the bipolar transistor structure can be controlled via the insulated gate electrodes arranged electrically separately.

### BRIEF DESCRIPTION OF THE DRAWINGS

The invention will now be explained in greater detail with reference to the attached drawing.

FIG. 1 shows a field effect semiconductor component 1 with bipolar transistor structure 2 in a semiconductor body 3 according to an embodiment.

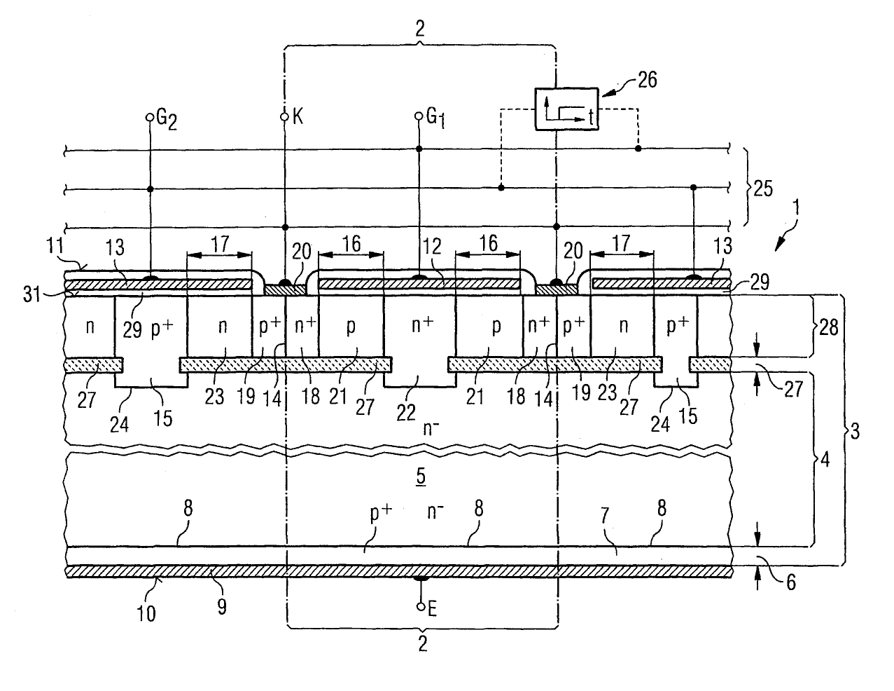

### DETAILED DESCRIPTION

The first insulated gate electrode may control an MOS channel of the first type of conduction and, when the field effect semiconductor component is operating, may supply the base region with majority charge carriers. The second insulated gate electrode may control an MOS channel of the complementary type of conduction and, when the field effect semiconductor component is operating, may remove majority charge carriers from the collector region with complementary doping to the base region. The vertical pn junction region insulated from the upper area may comprise a heavily doped region of the first type of conduction and an adjoining heavily doped region of the complementary type of conduction, wherein the regions of the pn junction region are electrically connected to one another by a collector electrode. The first insulated gate electrode may act in conjunction with an MOS channel structure of the first type of conduction which has a body region of the complementary type of conduction which is insulated from the upper area, particularly from the base region, wherein the body region adjoins a heavily doped area of the base region which changes into the minority charge carrier diffusion region of lightly doped material of the first type of conduction in the upper area. The second insulated gate electrode may act in conjunction with an MOS channel structure of the complementary type of conduction which has a body region of the first type of conduction which is insulated from the upper area, particularly from the base region, wherein the body region adjoins a heavily doped collector region of the complementary type of conduction which has a pn junction to the base region. The field effect semiconductor component may have on its top a wiring pattern which connects a number of first insulated gates, a number of second insulated gates and a number of collector electrodes with one another. The field effect semiconductor component may have on its top a delay circuit which is connected to the wiring pattern in such a manner that first the MOS channel of the complementary type of conduction is switched through to the collector region and the MOS channel of the first type of conduction is only switched through to the heavily doped area of the base region with delay.

A method for producing field effect semiconductor components with bipolar transistor structure in a semiconductor body which is built up of a lightly doped upper area of a first type of conduction as base region and a lower heavily doped area as emitter region of a type of conduction complementary to the first type of conduction, may comprises the following method steps:
producing a semiconductor wafer of monocrystalline silicon with a high concentration of impurities of the complementary type of conduction as emitter region with semiconductor chip positions arranged in rows and columns;
depositing a lightly doped epitaxial layer as base region of the first type of conduction on the semiconductor wafer;
selectively introducing insulation regions into the area of the epitaxial layer close to the surface;
selectively doping the area close to the surface above the insulation regions introduced to form MOS channel structures of the first type of conduction and of the complementary type of conduction;
selectively doping the areas close to the surface adjacently to the insulation regions introduced to form heavily doped collector regions with complementary type of conduction and to form heavily doped base regions with the first type of conduction and simultaneously forming the vertical pn junction regions above the insulation regions;
selectively applying a gate oxide on the MOS channel regions;
selectively depositing gate electrodes and collector electrodes on the top of the semiconductor wafer in the semiconductor chip positions;
applying a wiring pattern in the semiconductor chip positions,
separating the semiconductor wafer into semiconductor chips;
packaging the semiconductor chips into field effect semiconductor components with corresponding external contacts (G₁, G₂, K and E).

For selectively introducing insulation regions close to the surface, an ion implantation of oxygen ions or nitrogen ions or carbon ions can be effected. Instead of insulation regions, cavities close to the surface can be selectively introduced. For selectively applying a gate oxide on the MOS channel regions, the top of the semiconductor wafer can be thermally oxidized and subsequently patterned by means of photolithography. For the selective doping, ion implantations can be effected by means of ion implantation masks, followed by thermal recrystallization and diffusion steps.

A field effect semiconductor component according to an embodiment has the advantage that one of the insulated gate electrodes activates the base region and the other one of the insulated gate electrodes activates the collector region. To activate the base region, majority charge carriers from the vertical pn junction region are injected into the base region with the appropriate potential at the first insulated gate whereas minority charge carriers which are injected into the base region from the emitter region of the conducting horizontal pn junction are removed from the collector region in the area of the field effect semiconductor component close to the surface by means of a suitable potential at the second insulated gate via the collector pn junction.

The prerequisite for this novel field effect semiconductor component structure to operate is that first the collector region is activated via the second gate electrode and then the activated base region controls the current from the emitter to the collector of this novel field effect semiconductor component via the first gate electrode. The prerequisite for such a field effect semiconductor component to operate is that the vertical pn junction region in the area close to the surface is electrically insulated from the upper area of the semiconductor body.

In a preferred embodiment of an embodiment, the first insulated gate electrode controls an MOS channel of the first type of conduction and, when the field effect semiconductor component is operating, supplies the base region with majority charge carriers. These majority charge carriers are controlled with the aid of the first insulated gate electrode via the MOS channel. The majority charge carriers for the base region are provided by the vertical pn junction region which is arranged insulated from the base region and is supplied by the collector electrode at the same time.

In one embodiment, the second insulated gate electrode controls an MOS channel of the complementary type of conduction and, when the field effect semiconductor component is operating, removes majority charge carriers from a collector region with complementary doping to the base region, for which purpose a collector pn junction in the upper area of the semiconductor body is operated in the reverse direction so that the minority charge carriers injected from the emitter, and thus from the rear of the semiconductor body, into the base region are removed from the collector pn junction. When the MOS channel for the collector and the MOS channel for the base region are thus conducting, a large emitter current can diffuse through the lightly doped base region to the collector.

The vertical pn junction region insulated from the upper area has a heavily doped region of the first type of conduction and an adjoining heavily doped region of the second type of conduction, the two regions of the vertical pn junction region being electrically connected to one another by a collector electrode. As a result, the collector electrode can supply both the one MOS channel and the MOS channel with complementary doping with corresponding charge carriers.

The first insulated gate electrode thus advantageously acts in conjunction with an MOS channel structure of the first type of conduction which has a body region of the complementary type of conduction which is insulated from the upper area, particularly from the base region. For this purpose, the body region adjoins a heavily doped area of the base region which changes into the minority charge carrier diffusion region of lightly doped material of the first type of conduction in the upper area of the semiconductor body. This ensures that the base region can be controlled via the insulated first gate which acts on the body region of the complementary type of conduction.

The second insulated gate electrode acts in conjunction with an MOS channel structure of the complementary type of conduction which, in turn, has a body region of the first type of conduction which is insulated from the upper area, particulary from the base area. This body region adjoins a heavily doped collector region of the complementary type of conduction which has an upper horizontal pn junction with the base region. This collector pn junction connected in the reverse direction accepts the minority charge carriers of the base region injected from the emitter and conducts them via the body region of the first type of conduction to the collector electrode.

Compared with the prior art, the semiconductor component according to an embodiment has the advantage that only the area close to the surface is patterned whereas the area close to the rear of the field effect semiconductor component is constructed homogenously without any patterning which facilitates the production methods of such a semiconductor component and provides for cost-effective production.

In one embodiment, the field effect semiconductor component can have a delay circuit on its top. This delay circuit is connected to the wiring pattern of the field effect semiconductor component on the top in such a manner that first the MOS channel of the complementary type of conduction is switched through towards the collector region and the MOS channel of the first type of conduction is only switched through to the heavily doped area of the base region with delay. This delay element thus ensures that the field effect semiconductor component can respond to control signals at the first electrode since the collector region is already fully operational.

A method for producing field effect semiconductor components with bipolar transistor structure in a semiconductor body which is built up of a lightly doped upper area of a first type of conduction as base region and a lower heavily doped area as emitter region of a type of conduction complementary to the first type of conduction has the following method steps. Firstly, a semiconductor wafer of monocrystalline silicon with a high concentration of impurities of the complementary type of conduction is produced as emitter region with semiconductor chip positions arranged in rows and columns. Then a lightly doped epitaxial layer is deposited on this heavily doped substrate as base region of the first type of conduction on the semiconductor wafer.

Following that, insulation regions are selectively introduced into areas of the epitaxial layer close to the surface. After that, the areas close to the surface above the insulation regions introduced are selectively doped to form MOS channel structures of the first type of conduction and of the complementary type of conduction so that corresponding body regions form. Following that, the areas close to the surface are selectively doped adjacently to the insulation regions introduced to form heavily doped collector regions with complementary type of conduction and to form heavily doped base contact regions with the first type of conduction, simultaneously forming the vertical pn junction regions above the insulation regions.

Following that, a gate oxide is selectively applied to the MOS channel regions. Finally, gate electrodes and collector electrodes can be deposited on the top of the semiconductor wafer in the semiconductor chip positions. After that, a wiring pattern is applied in the semiconductor chip positions and then the semiconductor wafer is separated into semiconductor chips. Finally, the semiconductor chips are packaged into field effect semiconductor components with corresponding external contacts and internal wiring lines.

This method has the advantage that complementary MOS structures are applied to the lightly doped base region of a bipolar transistor structure by means of processing close to the surface. For this purpose, the MOS structures are advantageously largely electrically separated from the base region of the bipolar transistor structure by a buried insulation layer. This creates a clear functional separation between a first insulated gate which represents the insulated gate of the bipolar transistor, and an insulated gate which is used for switching in the collector region of the bipolar transistor.

In a preferred example of carrying out the method, an ion implantation of oxygen ions or nitrogen ions or carbons ions is performed for introducing insulation regions close to the surface. In this process, the ion density and the ion energy is set in such a manner that a maximum of oxygen ions or nitrogen ions or carbon ions is produced in a layer removed from the surface of the semiconductor body by at least 0.3 to 3 μm so that regions of silicon dioxide, silicon nitride and/or silicon carbide form as insulation regions whereas monocrystalline silicon material remains above these after recrystallization cycles. Instead of insulation regions, cavities close to the surface can also be selectively provided in order to electrically insulate the insulation of the structures close to the surface from the base region of the bipolar transistor structure.

For selectively applying a gate oxide on the MOS channel regions, the top of the semiconductor wafer is thermally oxidized and subsequently patterned by means of photolithography, ensuring that both the first insulated gate electrode and the second insulated gate electrode are produced precisely in the areas required for switching through the collector region and the base region, respectively.

The selective doping is preferably performed by means of ion implantation by means of ion implantation masks, followed by thermal recrystallization and diffusion steps. This ensures that the crystal areas of the silicon disturbed by ion rays are repaired again to become monocrystalline regions with dopant concentrations on substitutional lattice sites.

In summary, the minority charge carrier current may be conducted on the collector side through an MOS switch. The switch used can be a p-channel MOS transistor. For this purpose, a buried insulated layer may be built into a semiconductor body, which allows majority charge carriers to be injected in a locally separated manner into the base of the pnp transistor and the minority charge carriers to be removed from the base. This buried insulated layer can consist, for example, of silicon dioxide or also of a cavity. Any other insulator allowing sufficient passivation of the boundary face to the silicon can also be used in this case. In the conducting state of the IGBT, a constant minority charge carrier density can be obtained over the base region of the IGBT, and, thus, a higher conductivity, as long as the recombination is negligible.

In one embodiment, the n-channel and the p-channel transistor are in each case simultaneously switched on and off, respectively. In one embodiment, however, it may be of advantage for the switching characteristic of the IGBT if the two MOS transistors are switched on and off at different times so that the p-channel transistor of the collector region is preferably switched slightly earlier for switching off the IGBT. This is achieved by separate driving of the IGBT or by means of a delay element between the two insulated gates of the MOS transistors.

A further advantage of the novel field effect semiconductor component consists in that the places on the collector side for injecting the majority charge carriers or for removing the minority charge carriers are located at different locations. Thus, the p-type region can be constructed to have as low a resistance and as large an area as possible, compared with conventional IGBT structures, which leads to shorter switching-off times.

The semiconductor body 3 consists of a heavily doped p−-conducting monocrystalline silicon substrate which forms the lower heavily doped area 6 with complementary type of conduction p⁺. This heavily doped lower area 6 with complementary type of conduction p⁺ forms the emitter region 7 of the bipolar transistor structure 2 with a large-area emitter electrode 9 for an emitter terminal E on the rear 10 of the field effect semiconductor component 1. On the lower heavily doped area 6, a lightly doped n⁻-conducting upper area 4 of the first type of conduction is arranged which forms the base region 5 of the bipolar transistor. A horizontal emitter pn junction 8 forms between the heavily doped lower area 6 and the lightly doped upper area 4. Between the lightly doped upper area 4 of the base region 5 and the top 31 of the semiconductor body 3, an area 28 close to the surface is arranged.

This area 28 close to the surface is partially electrically separated from the upper area 4 by an insulation region 27. This insulation region 27 can have silicon dioxide, silicon nitride or silicon carbide or can be formed by a cavity. The lightly doped n−-conducting base region 5 is connected to a heavily doped n⁺-conducting area 22 of the base region 5 close to the surface, which partially protrudes into the base region 5. In addition, a collector pn junction 24 protrudes into the base region 5, which is formed by a heavily doped p⁺-conducting collector region 15 in the area 28 close to the surface. In the area 28 close to the surface above the insulation region 27, a vertical pn junction 14, bridged by a collector electrode 20, of highly conductive p⁺ and n⁺ regions 18 and 19 is formed. With the appropriate collector potential at the collector electrode 20 and a conducting first insulated gate G₁, an N-MOS channel 16 forms in a p-conducting body region 21, which supplies the base region 5 with majority charge carriers via a heavily doped connecting area 22.

On the other hand, a p-MOS channel 17 forms above an n-conducting body region 23 in the area 28 close to the top, which p-MOS channel removes charge carriers from the collector region 15 and thus receives the minority charge carriers of the base region 5 which diffuse from the horizontal emitter pn junction between the p⁺-conducting substrate and the base region 5 to the collector pn junction 24. This field effect semiconductor component 1 achieves the result that not only the base can be controlled via the first insulated gate G₁ but the collector K can also be controlled via the second insulated gate G₂. As a result, the switching processes can be shortened considerably compared with conventional IGBT structures which is the advantage of this field effect semiconductor component 1.

To form the complementary MOS structures with an n-channel MOS component and a p-channel MOS component, an n-type body region 23 and a p-type body region 21 are arranged above the insulation regions 27 as mentioned above. In this arrangement, the first gate G₁ extends with its first insulated gate electrode 12 over the p-type body region 21 and the second gate G₂ extends with its second insulated gate electrode 13 over the second n-conducting body region 23. The gate electrodes 12 and 13 are insulated from the area 28 close to the top of the semiconductor body 3 by a gate oxide 29 on the top 31 of the semiconductor body 3.

On the top 11 of the field effect semiconductor component 1, a wiring pattern 25 with conductor tracks is arranged which connects the collector electrodes 20 with a collector terminal K and connects the gate electrodes 12 with a first gate terminal G₁, and the gate electrodes 13 with a second gate terminal G₂. The gate electrodes G₁, and G₂ can be activated simultaneously or activated successively with the aid of a delay circuit 26 in order to be able to perform even faster switching processes.

List of Reference Designations

1 Field effect semiconductor component
2 Bipolar transistor structure
3 Semiconductor body
4 Lightly doped upper area
5 Base region
6 Lower heavily doped area with complementary type of conduction
7 Emitter region
8 Horizontal pn junction (emitter pn junction)
9 Large-area electrode (emitter electrode)
10 Rear of the field effect component
11 Top of the field effect component
12 First insulated gate electrode
13 Second insulated gate electrode
14 Vertical pn junction
15 Collector region
16 n-MOS channel for base region
17 p-MOS channel for collector region
18 Heavily doped region of the first type of conduction
19 Heavily doped region of the second type of conduction
20 Collector electrode
21 Body region of the complementary type of conduction
22 Heavily doped connecting area of the base region
23 Body region of the first type of conduction
24 Collector pn junction
25 Wiring pattern
26 Delay circuit
27 Insulation regions
28 Area close to the surface
29 Gate oxide
31 Top of the semiconductor body
E Emitter
G₁ First gate (n-MOS channel)
G₂ Second gate (p-MOS channel)
K Collector

What is claimed is:

1. A field effect semiconductor component with bipolar transistor structure in a semiconductor body which is built up of a lightly doped upper area of a first type of conduction as base region and a lower heavily doped area as emitter region of a type of conduction complementary to the first type of conduction, wherein a pn junction extends horizontally between the two areas and wherein the emitter region is in ohmic contact with a large-area electrode on a bottom surface of the field effect semiconductor component and, on a top surface of the field effect semiconductor component, a first insulated gate electrode and a second insulated gate electrode are arranged adjacently to a vertical pn junction region close to the top surface and insulated from the upper area, in such a manner that a collector region and the base region of the bipolar transistor structure are controllable via the insulated gate electrodes arranged electrically separately.

2. A field effect semiconductor component according to claim 1, wherein the first insulated gate electrode controls an MOS channel of the first type of conduction and, when the field effect semiconductor component is operating, supplies the base region with majority charge carriers.

3. A field effect semiconductor component according to claim 1, wherein the second insulated gate electrode controls an MOS channel of the complementary type of conduction and, when the field effect semiconductor component is operating, removes majority charge carriers from the collector region with complementary doping to the base region.

4. A field effect semiconductor component according to claim 1, wherein the vertical pn junction region insulated from the upper area comprises a heavily doped region of the first type of conduction and an adjoining heavily doped region of the complementary type of conduction, wherein the regions of the pn junction region are electrically connected to one another by a collector electrode.

5. A field effect semiconductor component according to claim 2, wherein the first insulated gate electrode acts in conjunction with an MOS channel structure of the first type of conduction which has a body region of the complementary type of conduction which is insulated from the upper area, particularly from the base region, wherein the body region adjoins a heavily doped area of the base region which changes into the minority charge carrier diffusion region of lightly doped material of the first type of conduction in the upper area.

6. A field effect semiconductor component according to claim 3, wherein the second insulated gate electrode acts in conjunction with an MOS channel structure of the complementary type of conduction which has a body region of the first type of conduction which is insulated from the upper area, particularly from the base region, wherein the body region adjoins a heavily doped collector region of the complementary type of conduction which has a pn junction to the base region.

7. A field effect semiconductor component according to claim 1, wherein the field effect semiconductor component has on its top a wiring pattern which connects a number of first insulated gates, a number of second insulated gates and a number of collector electrodes with one another.

8. A field effect semiconductor component according to claim 1, wherein the field effect semiconductor component has on its top a delay circuit which is connected to the wiring pattern in such a manner that first the MOS channel of the complementary type of conduction is switched through to the collector region and the MOS channel of the first type of conduction is only switched through to the heavily doped area of the base region with delay.

9. A method for producing field effect semiconductor components with bipolar transistor structure in a semiconductor body which is built up of a lightly doped upper area of a first type of conduction as base region and a lower heavily doped area as emitter region of a type of conduction complementary to the first type of conduction, wherein the method comprises the following method steps:
producing a semiconductor wafer of monocrystalline silicon with a high concentration of impurities of the complementary type of conduction as emitter region with semiconductor chip positions arranged in rows and columns;
depositing a lightly doped epitaxial layer as base region of the first type of conduction on the semiconductor wafer;
selectively introducing insulation regions into the area of the epitaxial layer close to the surface;
selectively doping the area close to the surface above the insulation regions introduced to form MOS channel structures of the first type of conduction and of the complementary type of conduction;
selectively doping the areas close to the surface adjacently to the insulation regions introduced to form heavily doped collector regions with complementary type of conduction and to form heavily doped base regions with the first type of conduction and simultaneously forming the vertical pn junction regions above the insulation regions;
selectively applying a gate oxide on the MOS channel regions;
selectively depositing gate electrodes and collector electrodes on the top of the semiconductor wafer in the semiconductor chip positions;
applying a wiring pattern in the semiconductor chip positions,
separating the semiconductor wafer into semiconductor chips;
packaging the semiconductor chips into field effect semiconductor components with corresponding external contacts (G₁, G₂, K and E).

10. A method according to claim 9, wherein, for selectively introducing insulation regions close to the surface, an ion implantation of oxygen ions or nitrogen ions or carbon ions is effected.

11. A method according to claim 9, wherein, instead of insulation regions, cavities close to the surface are selectively introduced.

12. A method according to claim 9, wherein, for selectively applying a gate oxide on the MOS channel regions, the top of the semiconductor wafer is thermally oxidized and subsequently patterned by means of photolithography.

13. A method according to claim 9, wherein, for the selective doping, ion implantations are effected by means of ion implantation masks, followed by thermal recrystallization and diffusion steps.

14. A bipolar transistor structure in a semiconductor body, comprising:
a base region comprising a lightly doped upper area of a first conductivity type in the semiconductor body,
an emitter region comprising a lower heavily doped area of a second conductivity type complementary to the first conductivity type,
a pn junction extending horizontally between the two areas,
a large-area electrode on a bottom of the semiconductor body being in ohmic contact with the emitter region, and
a first insulated gate electrode and a second insulated gate electrode arranged adjacently to a vertical pn junction region close to a top surface of the semiconductor body and insulated from the upper area, in such a manner that a collector region and the base region of the bipolar transistor structure are controllable via the insulated gate electrodes arranged electrically separately.

15. A bipolar transistor structure according to claim 14, wherein the first insulated gate electrode controls an MOS channel of the first conductivity type and supplies the base region with majority charge carriers.

16. A bipolar transistor structure according to claim 14, wherein the second insulated gate electrode controls an MOS channel of the second conductivity type and removes majority charge carriers from a collector region with complementary doping to the base region.

17. A bipolar transistor structure according to claim 14, wherein the vertical pn junction region insulated from the upper area comprises a heavily doped region of the first conductivity type and an adjoining heavily doped region of the second conductivity type, wherein the regions of the pn junction region are electrically connected to one another by a collector electrode.

18. A bipolar transistor structure according to claim 15, wherein the first insulated gate electrode acts in conjunction with an MOS channel structure of the first conductivity type which has a body region of the second conductivity type which is insulated from the upper area wherein the body region adjoins a heavily doped area of the base region which changes into the minority charge carrier diffusion region of lightly doped material of the first conductivity type in the upper area.

19. A bipolar transistor structure according to claim 16, wherein the second insulated gate electrode acts in conjunction with an MOS channel structure of the second conductivity type which has a body region of the first conductivity type which is insulated from the upper area, wherein the body region adjoins a heavily doped collector region of the second conductivity type which has a pn junction to the base region.

20. A bipolar transistor structure according to claim 14, further comprising on its top surface a wiring pattern which connects a plurality of first insulated gates, a plurality of second insulated gates and a plurality of collector electrodes with one another.

21. A bipolar transistor structure according to claim 14, further comprising on its top surface a delay circuit which is connected to the wiring pattern in such a manner that first the MOS channel of the second conductivity type is switched through to the collector region and the MOS channel of the first conductivity type is only switched through to the heavily doped area of the base region with delay.
